(19) United States
(12) Patent Application Publication
(10) Pub. No.: US 2013/0167361 A1
(43) Pub. Date: Jul. 4, 2013

(54) ELECTRONIC COMPONENT MOUNTING DEVICE AND ELECTRONIC COMPONENT MOUNTING METHOD

(71) Applicants: Teppei Kawaguchi, Yamanashi (JP); Michiaki Mawatari, Yamanashi (JP)

(72) Inventors: Teppei Kawaguchi, Yamanashi (JP); Michiaki Mawatari, Yamanashi (JP)

(73) Assignee: PANASONIC CORPORATION, Osaka (JP)

(21) Appl. No.: 13/821,052

(22) PCT Filed: Aug. 23, 2011
(86) PCT No.: PCT/JP2011/004675

§ 371 Date: Mar. 6, 2013

(30) Foreign Application Priority Data
Sep. 14, 2010 (JP) 2010-205121

(51) Int. Cl. H05K 7/00

(52) U.S. Cl. CPC H05K 7/00
USPC 29/592.1; 29/729

(57) ABSTRACT

When a connected position detecting unit detects that a connected position of a tape reaches a predetermined position in the tape passage, head-feeding of an electronic component provided in a head of the connected new tape is provided. In the head-feeding, a tape feeder feeds the tape such that the electronic component in the head of the new tape is located in a component pickup port. When the connected position detecting unit detects that the connected position of the tape reaches the predetermined position in the tape passage, a mounting head picks up the electronic component from the new tape fed by the head feeding control unit and is mounted on a new board positioned by a board conveying path.

### TECHNICAL FIELD

The present invention relates to an electronic component mounting device and an electronic component mounting method in which an electronic component fed by a tape feeder is picked up by a mounting head to mount the electronic component on a board.

### BACKGROUND ART

An electronic component mounting device includes a board conveying path which conveys and positions a board on which electronic component is to be mounted, a tape feeder which carries out a feeding operation of a tape storing electronic components to supply the electronic components; and a mounting head which picks up the electronic component supplied by the tape feeder and mounts the electronic component on the board positioned by the board conveying path. The tape feeder feeds the detachably attached tape pitch by pitch and supplies the electronic component stored in the tape to a component pickup port one by one. The mounting head picks up the electronic components supplied by the tape feeder and mounts the electronic component on the board positioned by the board conveying path. From the viewpoint that a quality control of the electronic component to be mounted on the board can be carried out for each tape, the electronic components having the same electrical characteristics are stored in the same tape.

When the feeding operation of the tape progresses and a rear end of the tape reaches the component pickup port, the tape attached to the tape feeder falls within a state of running out of the component and waiting for an exchange of the tape. A tape splicing technique is known for the purpose of eliminating a loss of time due to such a waiting for an exchange of a tape. In the tape splicing, a new tape is connected (spliced) to a rear end portion of a tape which is being attached to a tape feeder and supplying electronic component before the tape feeder runs out of the component, whereby the tape feeder can continuously supply the electronic component over a plurality of tapes (for example, Patent Document 1).

### RELATED ART DOCUMENTS

### Patent Documents

Patent Document 1: JP-A-2005-116599

### SUMMARY OF THE INVENTION

### Problem to be Solved by the Invention

However, when the tape splicing is applied, the electrical characteristics of the electronic component supplied from the tapes are different before and after connected positions of the tapes. When a plurality of electronic components which stride over the connected positions of the tapes are supplied and mounted on one board, the electronic components having different electrical characteristics are mixed and mounted on the board. Consequently, the tape splicing is extremely effective for the production of the board in which variation in the electrical characteristics of the electronic components mounted on the board is permitted to some degree. In contrast, the tape splicing may be rather inconvenient for a board such as an illumination panel, e.g., a liquid crystal panel, in which variation in electrical characteristics of mounted electronic components (LED components) may give a great influence to the quality of a product (here, a uniformity of illumination distribution) so that the quality of an entire board may be deteriorated.

An object of the present invention is to provide an electronic component mounting device and an electronic component mounting method in which even when the tape splicing is applied to the tape of the tape feeder, the electronic components having the same electrical characteristics can be mounted to one board.

### Means for Solving the Problem

An aspect of the present invention provides an electronic component mounting device including: a board conveying path which conveys and positions a board for mounting an electronic component thereon; a tape feeder which feeds pitch by pitch a tape storing the electronic components to be mounted on the board so as to supply one by one the electronic components to a component pickup port; a mounting head which picks up the electronic component supplied by the tape feeder to mount the electronic component on the board positioned by the board conveying path; a tape passage serving as a passage of the tape fed pitch by pitch by the tape feeder; connected position detecting means which detects that a connected position where a new tape is connected to the tape provided in the tape feeder reaches a predetermined position in the tape passage; and head-feeding control means which performs head-feeding of an electronic component provided in a head of the connected new tape, in which the tape feeder feeds the tape such that the electronic component in the head of the new tape is located in the component pickup port, when the connected position detecting means detects that the connected position of the tape reaches the predetermined position in the tape passage, wherein when the connected position detecting means detects that the connected position of the tape reaches the predetermined position in the tape passage, the mounting head picks up the electronic component from the new tape fed by the head feeding control means and is mounted on a new board positioned by the board conveying path.

Another aspect of the invention provides an electronic component mounting method by an electronic component mounting device that includes: a board conveying path which conveys and positions a board for mounting an electronic component thereon; a tape feeder which feeds pitch by pitch a tape which stores the electronic component is to be mounted on the board so as to supply one by one the electronic components to a component pickup port; a mounting head which picks up the electronic component supplied by the tape feeder to mount the electronic component on the board positioned by the board conveying path; a tape passage serving as a passage of the tape fed pitch by pitch by the tape feeder; and connected position detecting means which detects that a connected position where a new tape is connected to the tape provided in the tape feeder reaches a predetermined position in the tape passage, said electronic component mounting method including: a step of performing head-feeding of an electronic component provided in a head of the connected new tape, in which the tape feeder feeds the tape such that the electronic component in the head of the new tape is located in the component pickup port, when the connected position detecting means detects that the connected position of the tape reaches the predetermined position in the tape passage; and a step of picking up the electronic component by the mounting head from the new tape fed by the head feeding control means and mounting the electronic component on a new board positioned by the board conveying path when the connected position detecting means detects that the connected position of the tape reaches the predetermined position in the tape passage.

### Advantages of the Invention

In the present invention, when it is detected that the connected position of the tape reaches the predetermined position in the tape passage, the head-feeding process of the electronic component is performed to locate the electronic component in the head of the new connected tape in the component pickup port, and the mounting head picks up the electronic component from the new tape to which the head-feeding process has been performed and mounts the electronic component on the new board. Accordingly, even when a tape splicing is applied to the tape of the tape feeder, the electronic components having the same electrical characteristics can be mounted on the one board. Thus, it is possible to avoid a deterioration of quality of an entire board caused by mounting the electronic components having different electrical characteristics on the one board.

### BRIEF DESCRIPTION OF THE DRAWINGS

FIG. 1 is a perspective view of an electronic component mounting device according to an exemplary embodiment of the present invention.

FIGS. 2(a) and 2(b) are plan views of a multi-board substrate which holds a plurality of unit boards to which LED components are mounted by the electronic component mounting device according to the exemplary embodiment of the present invention.

FIG. 3 is a block diagram showing a control system of the electronic component mounting device according to the exemplary embodiment of the present invention.

FIGS. 4(a) and 4(b) are diagrams showing a procedure of a tape splicing process of a tape attached to a tape feeder provided in the electronic component mounting device according to the exemplary embodiment of the present invention.

FIGS. 5(a) and 5(b) are diagrams showing a connected position detecting sensor, and in the vicinity thereof, provided in the electronic component mounting device according to the exemplary embodiment of the present invention.

FIG. 6 is a flowchart showing a procedure of component mounting processes carried out by the electronic component mounting device according to the exemplary embodiment of the present invention.

### MODE FOR CARRYING OUT THE INVENTION

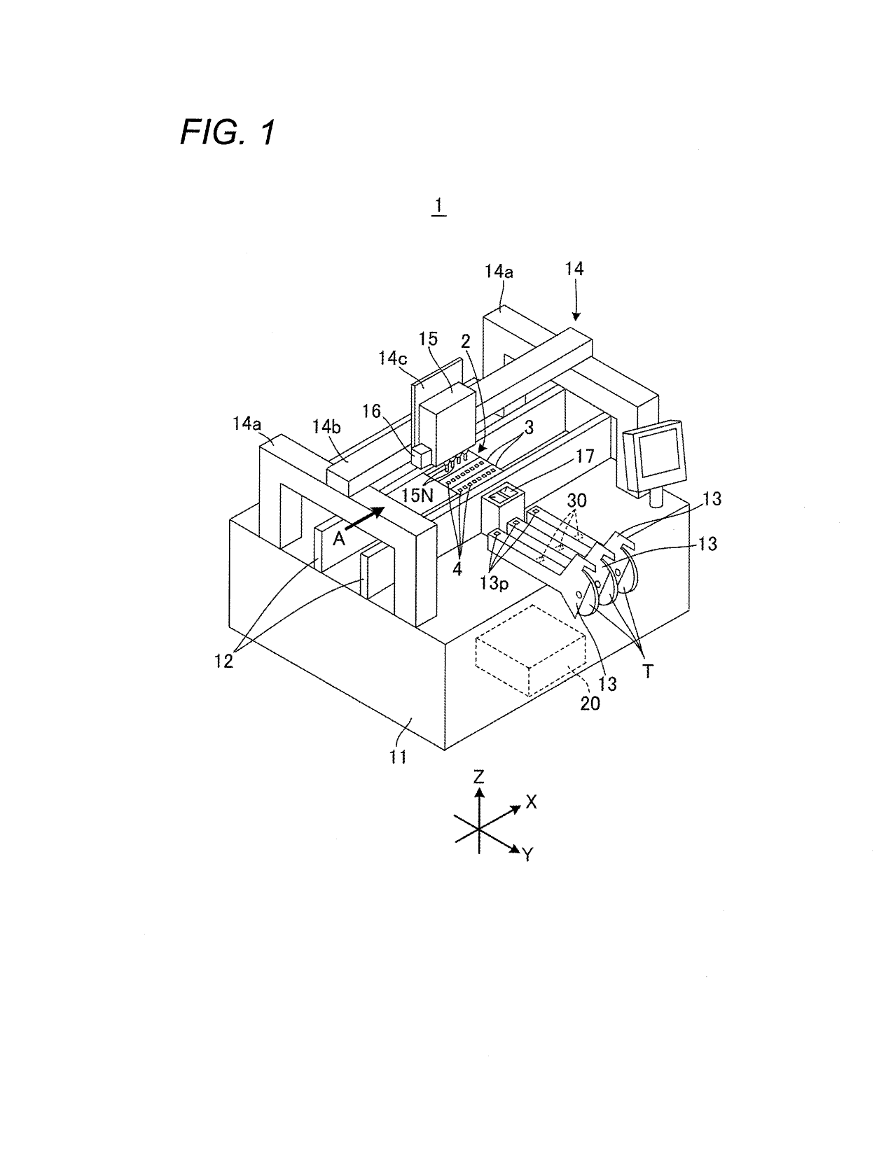

With reference to the drawings, an exemplary embodiment of the present invention will be described below. In FIG. 1, an electronic component mounting device 1 mounts LED components 4 serving as electronic components on a plurality of unit boards (hereinafter simply referred to as boards) 3, respectively, for manufacturing illumination boards held on a multi-board substrate 2 delivered from other device provided on an upstream side not shown and discharges the multi-board substrate 2 to other device provided on a downstream side not shown. The electronic component mounting device 1 is connected to other devices such as a screen printing device, an inspecting device or a re-flow furnace which are not shown to form a component mounting line for manufacturing mounting boards. For the convenience of a following explanation, a conveying direction of the multi-board substrate 2 in the electronic component mounting device 1 (in FIG. 1, a direction to which an arrow A is directed) is set to an X-axis direction, a direction along a horizontal plane and perpendicular to the X-axis direction is set to a Y-axis direction, and a vertical direction is set to a Z-axis direction. The Y-axis direction is set to a transverse direction of the electronic component mounting device 1.

In FIG. 1, the electronic component mounting device 1 includes: a board conveying path 12 provided on a base 11 to convey and position the multi-board substrate 2 (i.e., the boards 3) in a direction along a horizontal plane (the X-axis direction); a plurality of tape feeders 13 (three feeders in the exemplary embodiment) provided on one side of the base 11 in the Y-axis direction and arranged in parallel with the X-axis direction, each of which supplies the LED component 4 to be mounted on the boards 3; and a mounting head 15 which is movable by a head moving mechanism 14 provided on the base 11, picks up the LED component 4 supplied from the tape feeders 13, and mounts the LED component 4 on the boards 3 held by the multi-board substrate 2 on the board conveying path 12.

In FIG. 1, the board conveying path 12 includes a pair of belt conveyors. The board conveying path 12 conveys (loads) the multi-board substrate 2 delivered from other device on the upstream side (e.g., the screen printing machine) to position the multi-board substrate 2 at an operating position at a center of the base 11 (a position shown in FIG. 1), and conveys (unloads) the multi-board substrate 2 to which the LED component 4 is mounted by the mounting head 15 to discharge the multi-board substrate 2 to other device provided on the downstream side (e.g., the inspecting device).

In FIG. 1, each of the tape feeders 13 includes a detachable tape T which stores many LED components 4 having the same electrical characteristics arranged in one row. The tape feeder 13 feeds the tape T in a predetermined direction (here, in the Y-axis direction directed toward the board conveying path 12 side) pitch by pitch to continuously supply the LED components 4 one by one to components pickup ports 13p provided in an end portion of a center side of the base 11 (the board conveying path 12 side).

In FIG. 1, the head moving mechanism 14 includes one pair of gate type frames 14a provided so as to stride over the board conveying path 12 and extend in the Y-axis direction; a beam shaped X-axis table 14b having both ends supported on the pair of gate type frames 14a and provided movable in the Y-axis direction; and a plate shaped moving stage 14c provided movable in the X-axis direction on the X-axis table 14b. The mounting head 15 is attached to the moving stage 14c. The mounting head 15 includes a plurality of suction nozzles 15N extending downward such that the suction nozzles can be lifted and lowered and can rotate about the vertical axis (the Z-axis).

As shown in FIG. 1, in the mounting head 15, a board camera 16 having an imaging field of view directed downward is provided. In an area between the board conveying path 12 on the base 11 and the tape feeders 13, a component camera 17 having an imaging field of view directed upward is provided.

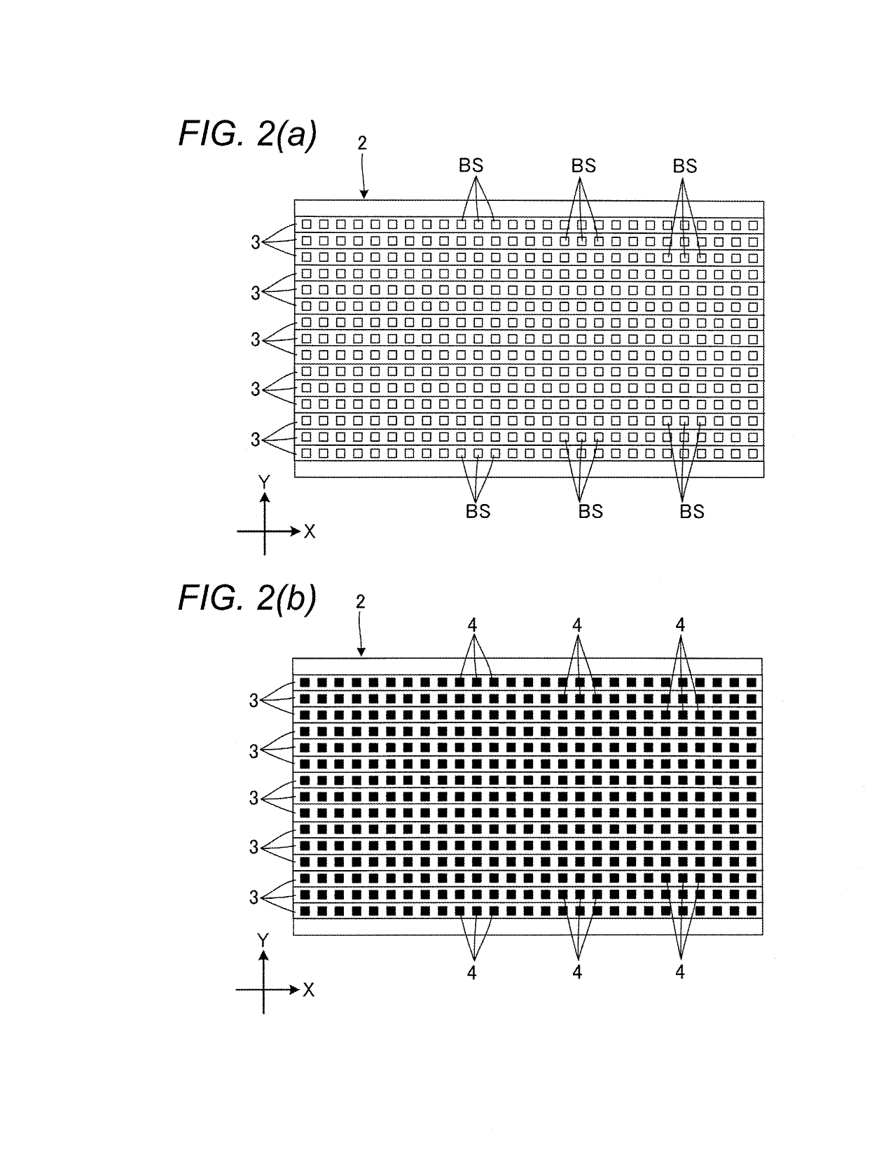

As shown in FIGS. 2(a) and 2(b), each of the boards 3 has an elongated form extending in the conveying direction (the X-axis direction) of the multi-board substrate 2 conveyed by the board conveying path 12. A plurality of boards 3 (fifteen sheets in the exemplary embodiment) are arranged in the direction of width of the multi-board substrate 2 (the Y-axis direction) and held on the multi-board substrate 2.

As shown in FIG. 2(a), in each of the boards 3, a plurality of LED component mounting portions BS are arranged in the conveying direction (the X-axis direction) of the board 2. The LED component mounting portions BS are provided for arranging and mounting thereon the LED components 4 of the same kind (the same color) in one row in the conveying direction of the multi-board substrate 2 (the X-axis direction). FIG. 2(a) shows the multi-board substrate 2 before the LED components 4 are mounted on the LED component mounting portions BS provided on each of the boards 3. FIG. 2(b) shows the multi-board substrate 2 after the LED components 4 are mounted on the LED component mounting portions BS provided on each of the boards 3.

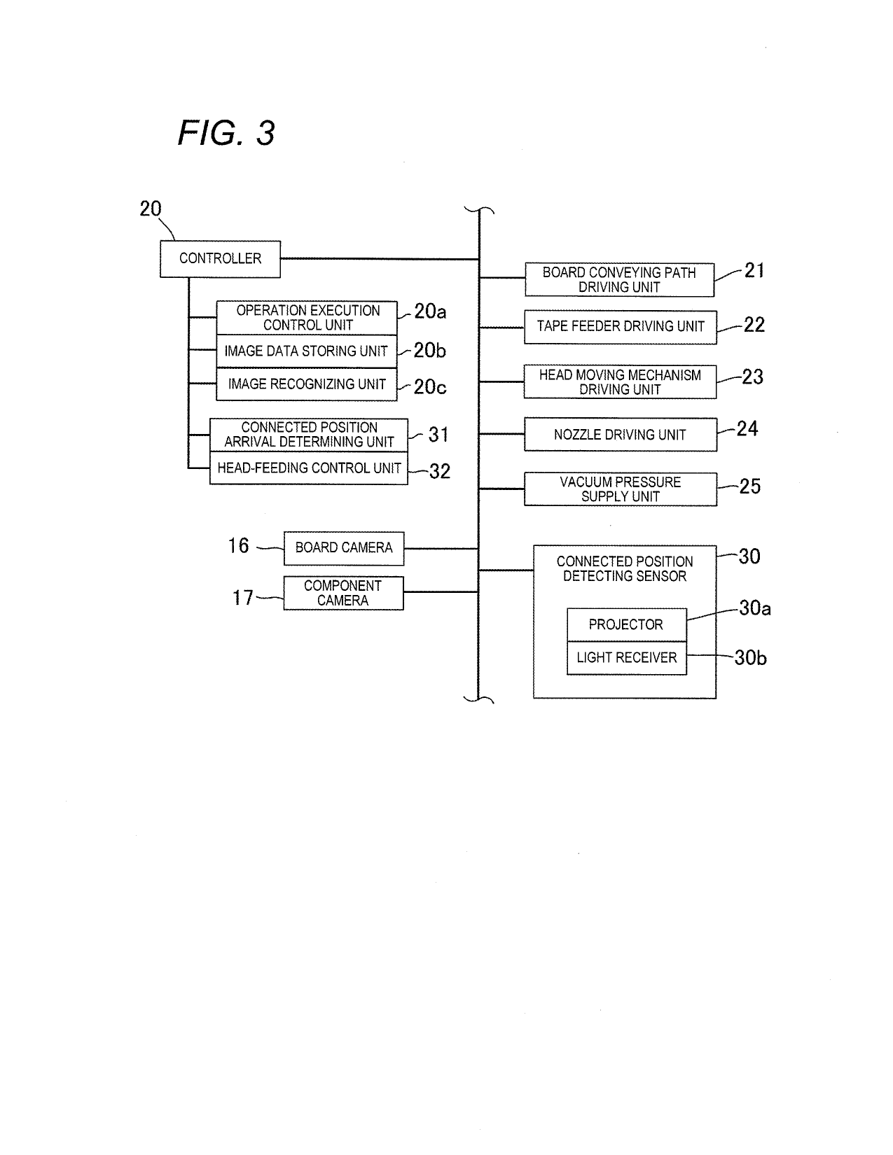

An operation execution control unit 20a (FIG. 3) of a controller 20 (FIG. 1 and FIG. 3) is provided in the electronic component mounting device 1. The operation execution control unit 20a controls an operation of a board conveying path driving unit 21 (FIG. 3) including an actuator not shown, thereby performing a conveying and positioning operation of the boards 3 (directly, the multi-board substrate 2) by the board conveying path 12. The operation execution control unit 20a of the controller 20 controls an operation of a tape feeder driving unit 22 (FIG. 3) including an actuator not shown, thereby performing a feeding operation (a pitch by pitch feeding operation of the tape T) of the LED component 4 to the component pickup port 13p by each of the tape feeders 13.

The operation execution control unit 20a of the controller 20 controls an operation of a head moving mechanism driving unit 23 (FIG. 3) (by controlling a movement of the X-axis table 14b in the Y-axis direction relative to the pair of gate type frames 14a and controlling a movement of the moving stage 14c in the X-axis direction relative to the X-axis stage 14b), thereby performing a moving operation of the mounting head 15 in the direction along the horizontal plane by the head moving mechanism 14. The operation execution control unit 20a of the controller 20 controls an operation of a nozzle driving unit 24 (FIG. 3) including an actuator not shown, thereby performing a lifting and lowering operation and a rotating operation of the suction nozzles 15N on the vertical axis relative to the mounting head 15.

The operation execution control unit 20a of the controller 20 controls an operation of a vacuum pressure supply unit 25 (FIG. 3) so as to supply a vacuum pressure to the suction nozzles 15N and release the supply of the vacuum pressure to the suction nozzles 15N, thereby performing a sucking and detaching operation of the LED component 4 by each of the suction nozzle 15N.

The operation execution control unit 20a of the controller 20 controls operations of the board camera 16 and the component camera 17 (FIG. 3), thereby performing an imaging operation by the board camera 16 and the component camera 17. Data of an image obtained by the imaging operations of the board camera 16 and the component camera 17 are fetched and stored in an image data storing unit 20b (FIG. 3), and the image is recognized by an image recognizing unit 20c (FIG. 3) provided in the controller 20.

When the feeding operation of the tape T by the tape feeder 13 progresses and a rear end portion of the tape T reaches the component pickup port 13p, the tape T attached to the tape feeder 13 falls within a state of running out of component. However, when a new tape T is connected (spliced) to the rear end portion of the tape T which is being attached to the tape feeder 13 and supplying the LED component 4 before the tape T runs out of the component as described above, the tape feeder 13 may continuously supply the LED components 4 over a plurality of tapes.

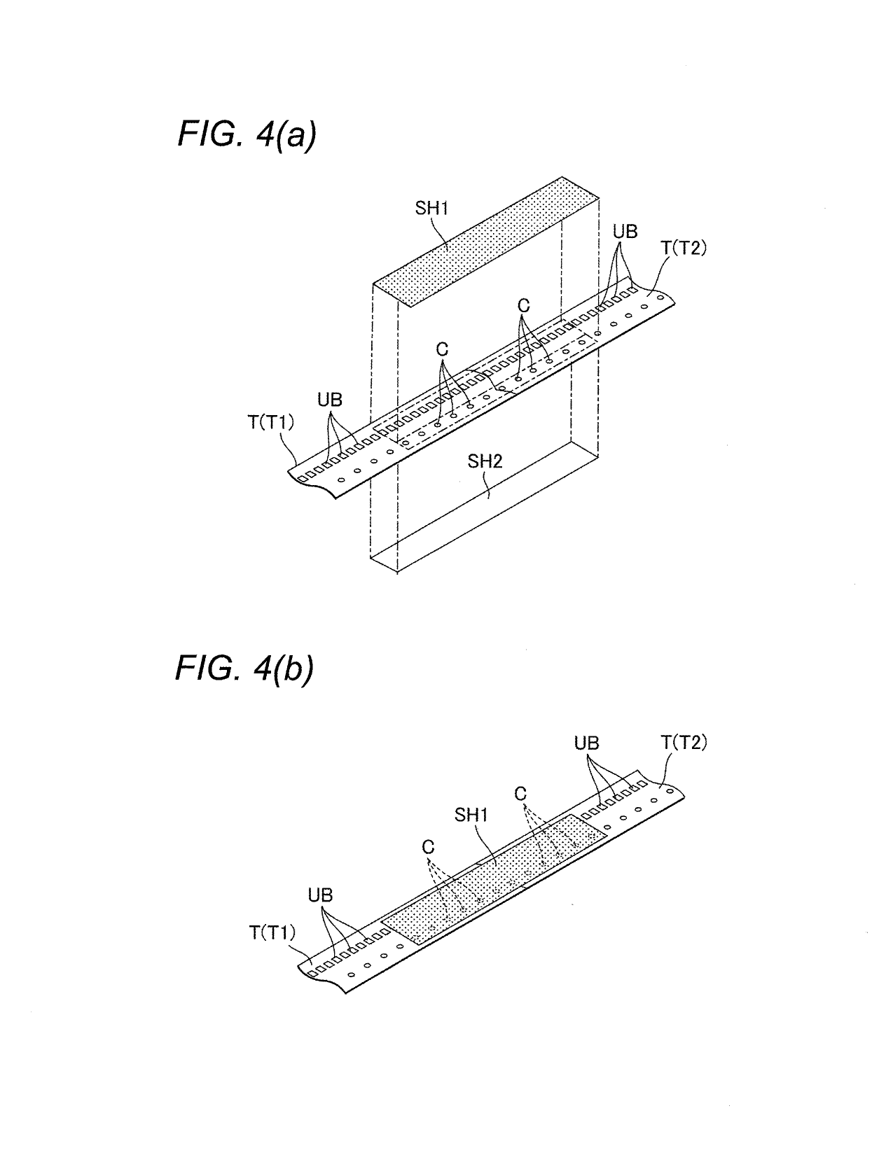

FIGS. 4(a) and 4(b) show an example of a procedure of a tape splicing operation. On an upper surface of the tape T, many recessed portion UB which stores the LED components 4 are arranged and provided in one row along the longitudinal direction of the tape T. On a side of the row (on a side in the direction of width of the tape T), many feeding holes C are similarly arranged and provided in one row along the longitudinal direction of the tape T. The feeding holes C are holes for fitting thereto outer peripheral protrusions of a sprocket (not shown) for feeding pitch by pitch the tape T provided in the tape feeder 13.

In order to connect the tapes T each other, at first, the rear end portion of the tape T (reference sign: T1, in FIGS. 4(a) and 4(b)) which is being attached to the tape feeder 13 and supplying the LED component 4 is butted against a leading end of the tape T (reference sign: T2, in FIGS. 4(a) and 4(b)) connected to the tape T. In this state, an upper connecting sheet SH1 is stuck to the upper surfaces of the tapes T1 and T2, and a lower connecting sheet SH2 is stuck to lower surfaces of the tapes T1 and T2 (FIG. 4(a) to FIG. 4(b)). The upper connecting sheet SH1 is positioned to dose the feeding holes C, and the lower connecting sheet SH2 is positioned to dose the feeding holes C.

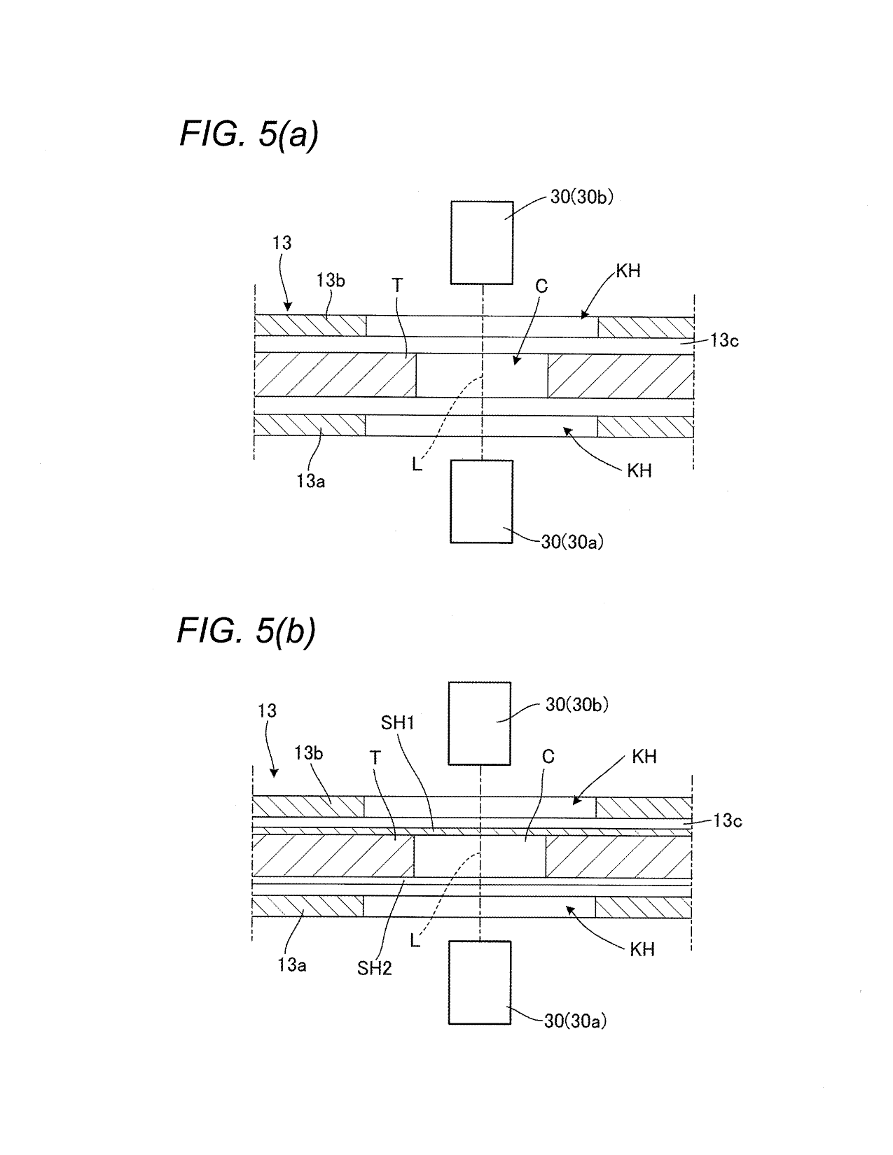

In FIGS. 5(a) and 5(b), the tape feeder 13 includes a tape lower support portion 13a and a tape upper support portion 13b which extend in the horizontal direction. The tape lower support portion 13a and the tape upper support portion 13b are provided to extend in the direction in the horizontal plane. The tape lower support portion 13a and the tape upper support portion 13b define a tape passage 13c as a passage of the tape T. At positions of the tape lower support portion 13a and the tape upper support portion 13b which vertically oppose each other, one pair of inspection light through holes KH are provided. The feeding holes C of the tape T fed pitch by pitch by the tape feeder 13 pass in the direction in the horizontal plane (the Y-axis direction) between the pair of inspection light through holes KH.

As shown in FIGS. 5(a) and 5(b), a connected position detecting sensor 30 (see also FIG. 1) is provided at positions to vertically sandwich the pair of inspection light through holes KH in the tape passage 13c of the tape feeder 13. The connected position detecting sensor 30 includes: a projector 30a provided below the tape lower support portion 13a to project inspection light L upward; and a light receiver 30b provided above the tape upper support portion 13b to receive the inspection light L projected by the projector 30a. When the light receiver 30b receives the inspection light L, the light receiver 30b outputs a light receiving signal to the controller 20.

As shown in FIG. 5(a), when a portion except a connected position of the tape T passes between the pair of inspection light through holes KH, the inspection light L projected by the projector 30a passes through the feeding holes C of the tape T from a lower side to an upper side for each of feeding operations of one pitches of the tape T by the tape feeder 13. Accordingly, the light receiver 30b intermittently receives the inspection light L at intervals of feeding times of one pitches of the tape T. However, as shown in FIG. 5(b), when the connected position of the tape T reaches the pair of inspection light through holes KH, since the inspection light L projected by the projector 30a is blocked by the upper connecting sheet SH1 which is stuck to close the feeding holes C of the tape T, the light receiver 30b does not receive the inspection light L during that time.

When a connected position arrival determining unit 31 (FIG. 3) of the controller 20 detects that output intervals of the light receiving signals output from the light receiver 30b at predetermined intervals up to that time are long despite that the tape T is fed pitch by pitch (when the light receiving signal from the connected position detecting sensor 30 (the light receiver 30b) is not received even when a predetermined time elapses), the connected position arrival determining unit 31 determines that the connected position of the tape T fed pitch by pitch by the tape feeder 13 reaches a predetermined position (a position between the pair of inspection light through holes KH) based on the light receiving signals output from the light receiver 30b.

In the present exemplary embodiment, the connected position detecting sensor 30 serves as connected position detecting means which detects that the connected position where the new tape T is connected to the tape T provided in the tape feeder 13 reaches the predetermined position in the tape passage 13c.

In FIG. 3, the controller 20 includes a head-feeding control unit 32. When the connected position detecting sensor 30 detects the connected position of the tape T, the head-feeding control unit 32 performs a “head-feeding the LED component 4” by controlling the operation of the tape feeder driving unit 22 to allow the tape feeder 13 to feed the tape T and supply the LED component 4 provided in a head of the newly connected tape T to the component pickup port 13p.

A procedure of component mounting process performed by the electronic component mounting device 1 in the present exemplary embodiment will be described below. In this example, only one tape feeder 13 of the three tape feeders 13 is supposed to supply the LED component 4, and the tape T is supposed to be connected by the new tape T before the tape T runs out of component. Accordingly, when the rear end portion of the tape T which is being attached to the tape feeder 13 and supplying the LED component 4 reaches the predetermined position (the position between the pair of inspection light through holes KH) by the feeding operation of the tape T by the tape feeder 13, the connected position of the tape T is always detected by the connected position detecting sensor 30.

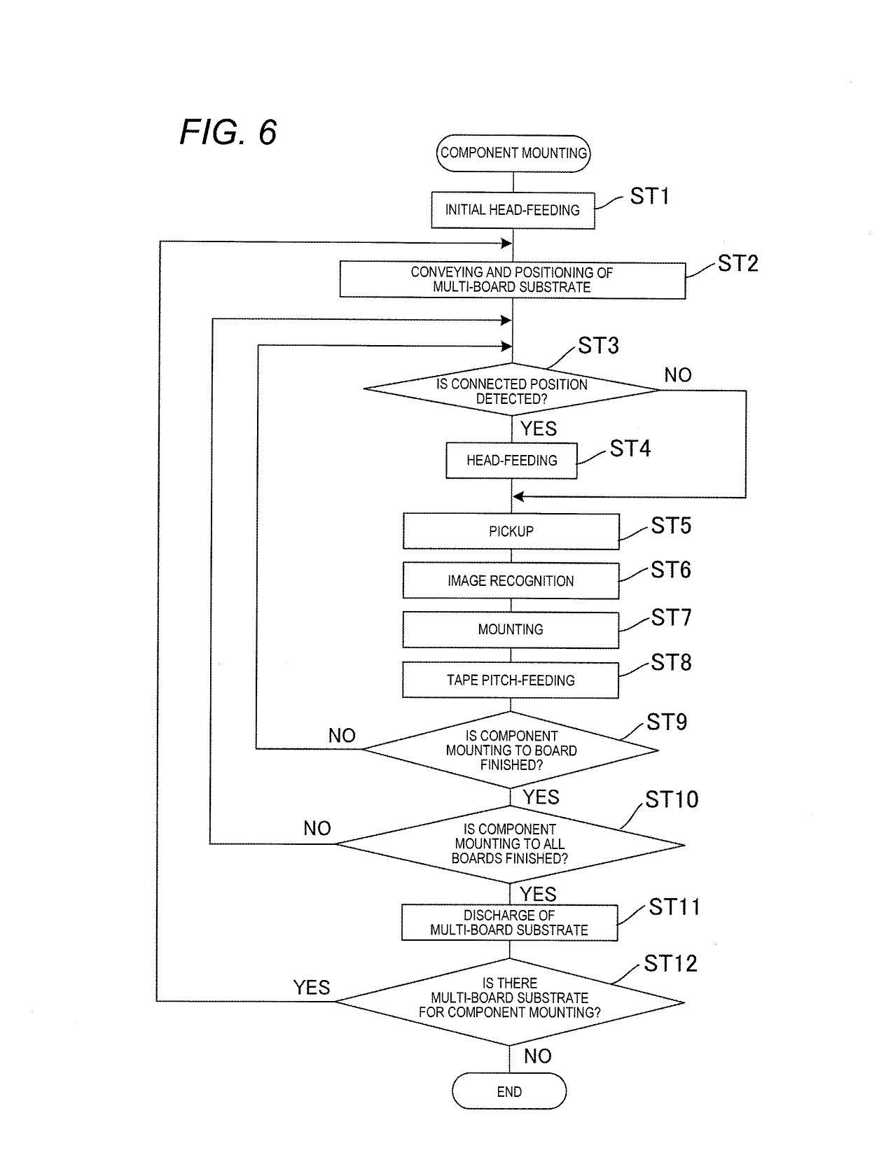

The operation execution control unit 20a of the controller 20 initially controls the operation of the tape feeder driving unit 22 to allow the tape feeder 13 to feed the tape T pitch by pitch so as to locate the LED component 4 in the head of the tape T which is being attached to the tape feeder 13 in the component pickup port 13p, thereby feeding the head LED component (initial head-feeding) (an “initial head-feeding” process in step ST1 shown in FIG. 6).

When the operation execution control unit 20a of the controller 20 performs the initial head-feeding process of the LED component 4, the operation execution control unit 20a controls the operation of the board conveying path driving unit 21 to convey (load) the multi-board substrate 2 delivered from other device on the upstream side (e.g., the screen printing machine) by the board conveying path 12 and position the multi-board substrate 2 in a predetermined operating position (a “multi-board substrate conveying and positioning” process in step ST2 shown in FIG. 6).

When the multi-board substrate 2 is positioned at the predetermined operating position, the operation execution control unit 20a of the controller 20 moves the board camera 16 (the mounting head 15) to a space above the multi-board substrate 2 to obtain an image of a board mark (not shown) provided on the multi-board substrate 2. Then, the operation execution control unit 20a allows the image recognizing unit 20c to recognize the obtained image so as to obtain a positional shift or displacement of the multi-board substrate 2 from a normal operating position.

When the operation execution control unit 20a of the controller 20 conveys and positions the multi-board substrate 2, the operation execution control unit 20a determines, in the connected position arrival determining unit 31, whether the connected position of the tape T is detected based on the detected information from the connected position detecting sensor 30 at the last pitch-by-pitch feeding operation of the tape T (a “connected position detection determining” process in step ST3 shown in FIG. 6). As a result, when the operation execution control unit 20a of the controller 20 determines that the connected position of the tape T is detected by the connected position arrival determining unit 31, the operation execution control unit allows the tape feeder 13 to feed the tape T to perform a head-feeding process of the LED component 4 in which the LED component 4 in the head of the new connected tape T is located in the component pickup port 13 (a “head-feeding” process in step ST4 in FIG. 6).

After the determination of the above-described step ST3 by the operation execution control unit 20a of the controller 20 (when the operation execution control unit 20a determines that the connected position of the tape T is detected in the step ST3, after the head LED component 4 is fed in the step ST4 subsequent thereto), the operation execution control unit 20a allows the mounting head 15 to pick up the LED component 4 fed to the component pickup port 13p (a “pickup” process in step ST5 shown in FIG. 6).

After the pickup of the LED component 4, the operation execution control unit 20a moves the mounting head 15 such that the picked up LED component 4 passes above the component camera 17 to obtain an image of the LED component 4 by the component camera 17. Then, the obtained image is recognized by the image recognizing unit 20c to inspect whether there is an abnormality (a deformation or defect) of the LED component 4 and to obtain a positional shift or displacement (a suction shift) of the LED component 4 relative to the suction nozzle 15N (an “image recognizing” process in step ST6 shown in FIG. 6).

After recognition of the image of the LED component 4 picked up by the mounting head 15, the operation execution control unit 20a allows the mounting head 15 to move above the board 3 for mounting the LED component 4. Then, the operation execution control unit 20a allows the picked up LED component 4 to contact the LED component mounting portion BS on the board 3 (in the LED component mounting portion BS, a solder is previously printed by the screen printing machine disposed on the upstream side of the electronic component mounting device 1), and controls the operation of the vacuum pressure supply unit 25 to release the supply of the vacuum pressure to the suction nozzles 15N. Thus, the operation execution control unit 20a mounts the LED component 4 on the LED component mounting portion BS on the board 3 (a “mounting” process in step ST7 shown in FIG. 6).

In the mounting process of the step ST7, after the determination that the connected position of the tape T is detected in the step ST3 and head-feeding of the LED component 4 in the step ST4 subsequent thereto, the operation execution control unit 20a changes a target board 3 to which the LED component 4 is mounted such that the target board 3 is not the board 3 to which the LED component 4 has been mounted up to that time, but to a different new board 3, and mounts the LED component 4 on the changed new board 3.

In the multi-board substrate 2 (the multi-board substrate 2 being positioned by the board conveying path 12) holding a board 3 on which the LED component 4 has been mounted up to that time, if a board on which the LED component 4 has not yet been mounted, the “new board 3” corresponds to the board 3 with no LED component 4 mounted thereon (when there are a plurality of such boards 3, one of them). If there is no new board 3 in the multi-board substrate 2 holding the boards 3 all on which the LED component 4 is mounted so far, the multi-board substrate 2 being positioned by the board conveying path 12 is discharged, and the “new board 3” corresponds to one of a plurality of boards 3 held in the new conveyed and positioned multi-board substrate 2.

When the LED component 4 is mounted on the LED component mounting portion BS on the board 3, the operation execution control unit 20a of the controller 20 performs a position correction (including a rotation correction) of the suction nozzles 15N relative to the multi-board substrate 2 (i.e., relative to the board 3) so as to correct the positional shift of the multi-board substrate 2 obtained at the time of positioning the multi-board substrate 2 in the step ST2 and the suction shift of the LED component 4 obtained at the time of recognizing the image of the LED component 4 in the step ST6.

After one LED component 4 is mounted on the board 3 (on the LED component mounting portion BS), the operation execution control unit 20a of the controller 20 controls the operation of the tape feeder driving unit 22 to perform pitch feeding of the tape T so as to supply the next LED component 4 to the component pickup port 13p (a “tape pitch-feeding” process in step ST8 shown in FIG. 6). Then, the operation execution control unit 20a determines whether all LED components 4 to be mounted on the board 3 on which the LED component 4 is being mounted are completely mounted (a “component mounting finish determining” process in step ST9 shown in FIG. 6). As a result, when mounting of all the LED components 4 to be mounted to the board 3 on which the LED component 4 is being mounted is not finished, the operation execution control unit 20a repeats the processes of the step ST5 to ST8. When mounting of all the LED components 4 to be mounted on the board 3 on which the LED component 4 is being mounted is finished, the operation execution control unit 20a determines whether the mounting of the LED components 4 is finished to all the boards 3 of the multi-board substrate 2 on which the LED component 4 is being mounted (a process of a “component mounting finish decision of all boards” in step ST10 shown in FIG. 6).

When the mounting of the LED components 4 is determined in the step ST10 as being not finished for all the boards 3 of the multi-board substrate 2 on which the LED component 4, the operation execution control unit 20a returns to the step ST3 so as to perform the processes of the step ST5 to the step ST7 for the board 3 on which the LED components 4 are not mounted yet. On the other hand, when the mounting of the LED components 4 is determined as being finished for all the boards 3 of the multi-board substrate 2 on which the LED components 4 are being mounted, the operation execution control unit 20a operates the board conveying path 12 to discharge the multi-board substrate 2 being positioned by the board conveying path 12 to an outside of the electronic component mounting device 1 (a “multi-board substrate delivering” process in step ST11 shown in FIG. 6).

After the finish of the multi-board substrate delivering process in the step ST11, the operation execution control unit 20a of the controller 20 determines whether there is still a multi-board substrate 2 on which the LED components 4 are to be mounted (a board presence or absence determining process in step ST12 shown in FIG. 6). As a result, when there is the multi-board substrate 2 on which the LED components 4 are to be mounted, the operation execution control unit 20a of the controller 20 returns to the step ST2 so as to convey a new multi-board substrate 2. When there is no multi-board substrate 2 on which the LED components 4 are mounted, the operation execution control unit 20a finishes a series of “component mounting” processes.

As described above, the electronic component mounting device 1 in the exemplary embodiment includes: the board conveying path 12 which conveys and positions the board 3 for mounting the LED components 4 thereon; the tape feeder 13 which feeds pitch by pitch the tape T which stores the LED components 4 to be mounted on the board 3 one by one to the component pickup port 13p; the mounting head 15 which picks up the LED components 4 supplied from the tape feeder 13 to mount the LED components 4 on the board 3 positioned by the board conveying path 12; the tape passage 13c serving as the passage of the tape T fed pitch by pitch by the tape feeder 13; the connected position detecting sensor 30 serving as the connected position detecting means which detects that the connected position where the new tape T is connected to the tape T provided in the tape feeder 13 reaches the predetermined position in the tape passage 13c; and the head-feeding control means (the head-feeding control unit 32 of the controller 20) which performs head-feeding of an electronic component provided in a head of the connected new tape T, in which the tape feeder 13 feeds the tape T such that the LED component 4 in the head of the new tape T is located in the component pickup port 13p, when the connected position detecting sensor 30 detects that the connected position of the tape T reaches the predetermined position in the tape passage 13c. When the connected position detecting sensor 30 detects that the connected position of the tape T reaches the predetermined position in the tape passage 13c, the mounting head 15 picks up the LED component 4 from the new tape T fed by the head-feeding control means and mounted on the new board 3 positioned by the board conveying path 12.

Further, the electronic component mounting method in the exemplary embodiment is an electronic component mounting method by the electronic component mounting device 1 of the exemplary embodiment, and includes: a step of performing head-feeding of the LED component 4 provided in the head of the connected new tape T, in which the tape feeder 13 feeds the tape T such that the LED component 4 in the head of the new tape T is located in the component pickup port 13p, when the connected position detecting sensor 30 detects that the connected position of the tape T reaches the predetermined position in the tape passage 13c (the head-feeding process in the step ST4); and a step of picking up the LED components 4 by the mounting head 15 from the new tape T in which the LED components 4 is head-fed and mounting the LED components 4 on the new board 3 positioned by the board conveying path 12 when the connected position detecting sensor 30 detects that the connected position of the tape T reaches the predetermined position in the tape passage 13c (the pickup process in ST5 to the mounting process in the step ST7).

In the electronic component mounting device 1 and the electronic component mounting method according to the exemplary embodiment, when the connected position of the tape T is detected to reach the predetermined position in the tape passage 13c, the head-feeding process of the LED components 4 is performed such that the LED component 4 provided in the head of the new connected tape T is located in the component pickup port 13p. The mounting head 15 picks up the LED component 4 from the new tape T which has been subject to the head-feeding of the LED component 4, and mounts the LED component 4 on the new board 3. Accordingly, even when a tape splicing is applied to the tape T of the tape feeder 13, the LED components 4 having the same electrical characteristics can be mounted on the one board 3. Thus, it is possible to avoid a deterioration of quality of an entire board 3 caused by mounting the electronic components 4 having different electrical characteristics on the one board 3.

In a related art, the mounting head picks up the LED components 4 obtained by striding over the connected position of the tapes subjected to tape splicing, and continuously mounts the LED components 4 on the same board. The electronic component mounting device 1 according to the exemplary embodiment is different from the related art in that it is ensured that the LED components 4 having the different electrical characteristics are not mounted on the same board 3 on which all the LED components 4 to be mounted are completely mounted. Consequently, it is not necessary to check the board 3 to which the LED components 4 are completely mounted whether the LED components 4 having the different electrical characteristics are mounted. Thus, such an operation can be omitted.

Although the exemplary embodiment of the present invention is explained as described above, the present invention is not limited to the above-described exemplary embodiment. For example, in the above-described embodiment, the LED component is explained as the electronic component fed by the tape feeder 13. However, the electronic component fed by the tape feeder 13 is not limited to the LED component, and may be other electronic components.

Further, in the above-described exemplary embodiment, the illumination board is explained as the board (the unit board 3) as an object on which the electronic component is mounted. However, the board is not limited to the illumination board. Further, in the above-described embodiment, for the board (the unit board 3) as an object on which the electronic component is mounted, a plurality of boards are held on the multi-board substrate 2. However, the boards may not be necessarily held on the multi-board substrate 2.

The present invention is described in detail with reference to the specific exemplary embodiment. However, it is to be understood to a person having ordinary skill in the art that various changes or modifications may be made without departing from the spirit and scope of the present invention.

This application is based on Japanese Patent Application (Application No. 2010-205121) filed on Sep. 14, 2010, and contents of which are incorporated by reference.

### INDUSTRIAL APPLICABILITY

Provided are electronic component mounting device and the electronic component mounting method in which even when the tape splicing is applied to the tape of the tape feeder, the electronic components having the same electrical characteristics can be mounted to one board.

### DESCRIPTION OF REFERENCE SIGNS

1 Electronic Component Mounting Device
2 Multi-Board Substrate
3 Board
4 LED Component (Electronic Component)
12 Board Conveying Path
13 Tape Feeder
13c Tape Passage
13p Component Pickup Port
15 Mounting Head
30 Connected Position Detecting Sensor (Connected Position Detecting Means)
32 Head-Feeding Control Unit (Head-Feeding Control Means)
T, T1, T2 Tape

1. An electronic component mounting device comprising:
a board conveying path which conveys and positions a board for mounting an electronic component thereon;
a tape feeder which feeds pitch by pitch a tape storing the electronic components to be mounted on the board so as to supply one by one the electronic components to a component pickup port;
a mounting head which picks up the electronic component supplied by the tape feeder to mount the electronic component on the board positioned by the board conveying path;
a tape passage serving as a passage of the tape fed pitch by pitch by the tape feeder;
a connected position detecting unit which detects that a connected position where a new tape is connected to the tape provided in the tape feeder reaches a predetermined position in the tape passage; and
a head-feeding control unit which performs head-feeding of an electronic component provided in a head of the connected new tape, in which the tape feeder feeds the tape such that the electronic component in the head of the new tape is located in the component pickup port, when the connected position detecting unit detects that the connected position of the tape reaches the predetermined position in the tape passage,
wherein when the connected position detecting unit detects that the connected position of the tape reaches the predetermined position in the tape passage, the mounting head picks up the electronic component from the new tape fed by the head feeding control unit and is mounted on a new board positioned by the board conveying path.

2. An electronic component mounting method by an electronic component mounting device that comprises: a board conveying path which conveys and positions a board for mounting an electronic component thereon; a tape feeder which feeds pitch by pitch a tape which stores the electronic component is to be mounted on the board so as to supply one by one the electronic components to a component pickup port; a mounting head which picks up the electronic component supplied by the tape feeder to mount the electronic component on the board positioned by the board conveying path; a tape passage serving as a passage of the tape fed pitch by pitch by the tape feeder; and a connected position detecting unit which detects that a connected position where a new tape is connected to the tape provided in the tape feeder reaches a predetermined position in the tape passage,
said electronic component mounting method comprising:
performing head-feeding of an electronic component provided in a head of the connected new tape, in which the tape feeder feeds the tape such that the electronic component in the head of the new tape is located in the component pickup port, when the connected position detecting unit detects that the connected position of the tape reaches the predetermined position in the tape passage; and
picking up the electronic component by the mounting head from the new tape fed by the head feeding control unit and mounting the electronic component on a new board positioned by the board conveying path when the connected position detecting unit detects that the connected position of the tape reaches the predetermined position in the tape passage.
